(19) United States
(12) Patent Application Publication
(10) Pub. No.: US 2025/0393478 A1
(43) Pub. Date: Dec. 25, 2025

(54) SEMICONDUCTOR STRUCTURE AND MANUFACTURING METHOD THEREOF

(71) Applicant: United Microelectronics Corp., Hsinchu (TW)

(72) Inventors: Chia-Chang Hsu, Kaohsiung City (TW); Tang Chun Weng, Chiayi City (TW)

(73) Assignee: United Microelectronics Corp., Hsinchu (TW)

(21) Appl. No.: 18/770,688

(22) Filed: Jul. 12, 2024

(30) Foreign Application Priority Data
Jun. 24, 2024 (TW) 113123395

(51) Int. Cl. H10N 50/10; H10B 61/00; H10N 50/01

(52) U.S. Cl. CPC H10N 50/10; H10B 61/00; H10N 50/01

(57) ABSTRACT

A semiconductor structure includes a substrate having a memory device region and a peripheral region surrounding the memory device region, a memory device disposed on the substrate in the memory device region, and a dielectric layer disposed on the substrate, covering the memory device, having a surface on the memory device, and including an annular portion. The annular portion is located at a top of the dielectric layer, adjacent to a boundary between the memory device region and the peripheral region, and includes a vertical portion and an inclined portion adjacent to the vertical portion. Inner sidewalls of the vertical portion and the inclined portion form an inner sidewall of the annular portion. A height of the inclined portion is equal to or lower than a height of the vertical portion. The inclined portion is formed by a mask having a comb-shaped layout pattern. A manufacturing method is also provided.

### CROSS-REFERENCE TO RELATED APPLICATION

This application claims the priority benefit of Taiwan application serial no. 113123395, filed on Jun. 24, 2024. The entirety of the above-mentioned patent application is hereby incorporated by reference herein and made a part of this specification.

### BACKGROUND

### Technical Field

The disclosure relates to a semiconductor structure and a manufacturing method thereof, and particularly relates to a semiconductor structure including a memory device and a manufacturing method thereof.

### Description of Related Art

Memory devices, such as magnetoresistive random access memory (MRAM), are disposed during the back end of line (BEOL) process, and have little impact on the front end of line (FEOL) process. Therefore, it is easy to integrate with other semiconductor device processes to form a multi-tasking and efficient integrated circuit.

However, due to the characteristics of the memory device that is disposed in the back end of line process, there is a large height difference between the memory device and other peripheral components, such as logic components formed in the front end of line process, such that it causes the loading of subsequent comprehensive planarization (for example, chemical mechanical polishing (CMP)) after the dielectric layer is fully covered.

Therefore, often before comprehensive planarization, an etching-back process is performed on the dielectric layer in the memory device region that is higher than the peripheral component region after the dielectric layer is fully covered. A dielectric layer opening is formed in the memory device region, and an annular portion is left at the boundary between the memory device region and the peripheral component region, so as to reduce the thickness of the dielectric layer in the memory device region in advance, thereby reducing the height difference between the peripheral component region and the dielectric layer in the memory device region to reduce the loading of comprehensive planarization of the dielectric layer.

But after the etching-back, the remaining annular portion at the boundary between the memory device region and the peripheral region will bear great stress during the chemical mechanical polishing process, so it is easy for the entire piece to crack and be removed, causing a large-scale recess, such that when a circuit pattern is formed on the memory device in the subsequent process, the conductive material used to form the circuit pattern will fill in the recess, thereby resulting in a bridge problem.

Furthermore, the above-mentioned etching-back also often causes sub-trenches at the intersection between the bottom of the dielectric layer opening in the memory device region and the annular portion surrounding the memory device region, making the annular portion easier to break during the chemical mechanical polishing process, thereby making the above-mentioned large-scale recess more likely to occur; even if such a large-scale recess does not occur, these sub-trenches can easily accumulate residues from subsequent processes, causing negative electrical effects.

### SUMMARY

The disclosure provides a semiconductor structure, including: a substrate, including a memory device region and a peripheral region surrounding the memory device region; a memory device, disposed on the substrate in the memory device region; and a dielectric layer, disposed on the substrate, covering the memory device, having a surface on the memory device, and including an annular portion. The annular portion is located at a top of the dielectric layer and adjacent to a boundary between the memory device region and the peripheral region, and the annular portion includes: a vertical portion; and an inclined portion, adjacent to the vertical portion. An inner sidewall of the vertical portion and an inner sidewall of the inclined portion form an inner sidewall of the annular portion. A height of the inclined portion is equal to or lower than a height of the vertical portion, and the inclined portion is formed by a mask having a comb-shaped layout pattern.

In an embodiment of the semiconductor structure of the disclosure, the inclined portion has an inclination angle of 40 to 80 degrees relative to a surface of the dielectric layer.

In an embodiment of the semiconductor structure of the disclosure, the height of the inclined portion is 80 to 100% of the height of the vertical portion.

In an embodiment of the semiconductor structure of the disclosure, the comb-shaped layout pattern includes a comb beam portion and a comb tooth portion. A height of the comb tooth portion is 40 to 100% of a height of the comb beam portion, and a ratio of a width of the comb tooth portion to a spacing of the comb tooth portion is 1:2 to 1:3.

In an embodiment of the semiconductor structure of the disclosure, the inclined portion is formed by the mask having the comb-shaped layout pattern and a general lithography process, or the inclined portion is formed by the mask having the comb-shaped layout pattern and a defocused lithography process.

In an embodiment of the semiconductor structure of the disclosure, the defocused lithography process includes a deviation from a focus position by 0.3 to 0.8 microns.

In an embodiment of the semiconductor structure of the disclosure, the defocused lithography process includes a deviation from a target depth of field (DOF) by 70 to 90%.

In an embodiment of the semiconductor structure of the disclosure, the dielectric layer located in the memory device region further includes an auxiliary portion. The auxiliary portion is located at the top of the dielectric layer, is located in a region surrounded by the annular portion, and is concentric with the annular portion.

In an embodiment of the semiconductor structure of the disclosure, a top surface of the annular portion and a top surface of the auxiliary portion are coplanar.

In an embodiment of the semiconductor structure of the disclosure, the auxiliary portion includes one or more annular patterns when viewed from a top view above the substrate.

In an embodiment of the semiconductor structure of the disclosure, the auxiliary portion includes: an auxiliary vertical portion; and an auxiliary inclined portion, adjacent to the auxiliary vertical portion. An inner sidewall of the auxiliary vertical portion and an inner sidewall of the auxiliary inclined portion form an inner sidewall of the auxiliary portion. A height of the auxiliary inclined portion is equal to or lower than a height of the auxiliary vertical portion, and the auxiliary inclined portion is formed by the mask having the comb-shaped layout pattern.

In an embodiment of the semiconductor structure of the disclosure, the memory device includes a magnetic tunnel junction (MTJ) structure.

The disclosure provides a manufacturing method of a semiconductor structure, which includes: providing a substrate, where the substrate includes a memory device region and a peripheral region surrounding the memory device region; forming a memory device on the substrate in the memory device region; forming a dielectric layer on the substrate to cover the memory device; and patterning the dielectric layer to form a surface for the dielectric layer on the memory device, and form an annular portion at a top of the dielectric layer adjacent to a boundary between the memory device region and the peripheral region, where the annular portion includes: a vertical portion; and an inclined portion, adjacent to the vertical portion. An inner sidewall of the vertical portion and an inner sidewall of the inclined portion form an inner sidewall of the annular portion. A height of the inclined portion is equal to or lower than a height of the vertical portion, and the inclined portion is formed by a mask having a comb-shaped layout pattern.

In an embodiment of the manufacturing method of the semiconductor structure of the disclosure, the inclined portion has an inclination angle of 40 to 80 degrees relative to a surface of the dielectric layer.

In an embodiment of the manufacturing method of the semiconductor structure of the disclosure, the height of the inclined portion is 80 to 100% of the height of the vertical portion.

In an embodiment of the manufacturing method of the semiconductor structure of the disclosure, the comb-shaped layout pattern includes a comb beam portion and a comb tooth portion. A height of the comb tooth portion is 40 to 100% of a height of the comb beam portion, and a ratio of a width of the comb tooth portion to a spacing of the comb tooth portion is 1:2 to 1:3.

In an embodiment of the manufacturing method of the semiconductor structure of the disclosure, the inclined portion is formed by the mask having the comb-shaped layout pattern and a general lithography process, or the inclined portion is formed by the mask having the comb-shaped layout pattern and a defocused lithography process.

In an embodiment of the manufacturing method of the semiconductor structure of the disclosure, the defocused lithography process includes a deviation from a focus position by 0.3 to 0.8 microns.

In an embodiment of the manufacturing method of the semiconductor structure of the disclosure, the defocused lithography process includes a deviation from a target depth of field (DOF) by 70 to 90%.

In an embodiment of the manufacturing method of the semiconductor structure of the disclosure, while patterning the dielectric layer, it also includes forming an auxiliary portion on the dielectric layer located in the memory device region. The auxiliary portion is located at the top of the dielectric layer, is located in a region surrounded by the annular portion, and is concentric with the annular portion.

In an embodiment of the manufacturing method of the semiconductor structure of the disclosure, a top surface of the annular portion and a top surface of the auxiliary portion are coplanar.

In an embodiment of the manufacturing method of the semiconductor structure of the disclosure, the auxiliary portion includes one or more annular patterns when viewed from a top view above the substrate.

In an embodiment of the manufacturing method of the semiconductor structure of the disclosure, the auxiliary portion includes: an auxiliary vertical portion; and an auxiliary inclined portion, adjacent to the auxiliary vertical portion. An inner sidewall of the auxiliary vertical portion and an inner sidewall of the auxiliary inclined portion form an inner sidewall of the auxiliary portion. A height of the auxiliary inclined portion is equal to or lower than a height of the auxiliary vertical portion, and the auxiliary inclined portion is formed by the mask having the comb-shaped layout pattern.

In an embodiment of the manufacturing method of the semiconductor structure of the disclosure, the memory device includes a magnetic tunnel junction (MTJ) structure.

Based on the above, the mask having the comb-shaped layout pattern is used to simultaneously form the vertical portion and the inclined portion adjacent to the vertical portion on the dielectric layer.

Furthermore, the mask having the comb-shaped layout pattern can be used with a defocused lithography method to simultaneously form the vertical portion and the inclined portion adjacent to the vertical portion in the dielectric layer.

In addition, the inclined portion adjacent to the vertical portion can reinforce the vertical portion and prevent the annular dielectric layer from generating the sub-trench at the bottom of its inner sidewalls, such that cracks may be prevented from occurring at the bottom of the entire annular dielectric layer as a result of the sub-trench being subjected to excessive stress during the subsequent chemical mechanical polishing process, problems such as large-scale recesses resulting from the entire annular dielectric layer being cracked and removed may be prevented, underlying via plugs may be prevented from being exposed, or the conductive material used to form the circuit patterns may be prevented from filling in the recesses when forming circuit patterns on the memory device in subsequent processes so as to prevent bridging and other structures that have a negative impact on electrical properties from generating. It also solves the negative impact on the process and electrical properties caused by the existence of the sub-trench at the bottom of the inner sidewalls of the dielectric layer, where residues from subsequent processes accumulate.

### BRIEF DESCRIPTION OF THE DRAWINGS

FIG. 1A to FIG. 1C are schematic cross-sectional views of a manufacturing process of a semiconductor structure according to a first embodiment of the disclosure.

FIG. 2 is an enlarged view of the annular portion in FIG. 1C.

FIG. 3 is a schematic view of a mask having a comb-shaped layout pattern used in the annular portion in FIG. 1C.

FIG. 4 is an enlarged view of the comb-shaped layout pattern in FIG. 3.

FIG. 5 is a schematic cross-sectional view of a semiconductor structure according to a second embodiment of the disclosure.

FIG. 6 is a schematic view of a mask having a comb-shaped layout pattern used in the annular portion and the auxiliary portion in FIG. 5.

FIG. 7 is a schematic cross-sectional view of a semiconductor structure according to a third embodiment of the disclosure.

FIG. 8 is a schematic view of a mask having a comb-shaped layout pattern used in the annular portion and the auxiliary portion in FIG. 7.

### DESCRIPTION OF THE EMBODIMENTS

Hereinafter, exemplary embodiments will be described in detail with reference to the accompanying drawings, but the provided embodiments are not intended to limit the scope of the disclosure. In addition, the drawings are for illustrative purposes only and may not be drawn to scale. In order to facilitate understanding of the disclosure, the same elements will be denoted by the same reference numerals in the following description.

Terms such as “containing,” “including,” “having,” etc. used in this specification are all open-ended terms, that is, meaning “including but not limited to.”

When terms such as “first,” “second,” etc. are used to describe the elements, they are only used to distinguish these elements from each other and are not intended to limit the order or importance of the elements. Therefore, in some cases, the first element may also be referred to as the second element, and the second element may also be referred to as the first element, without departing from the scope of the disclosure.

In addition, directional terms such as “up,” “down,” etc. used in this specification only refer to the directions of the drawings and are not intended to limit the disclosure. Thus, it should be understood that “up” is used interchangeably with “down” and that when an element such as a layer or film is placed “on” another element, the element may be directly placed on another element, or there may be an intervening element. However, when an element is described as being “directly” placed “on” another element, there is no other intervening element between the two elements.

### First Embodiment

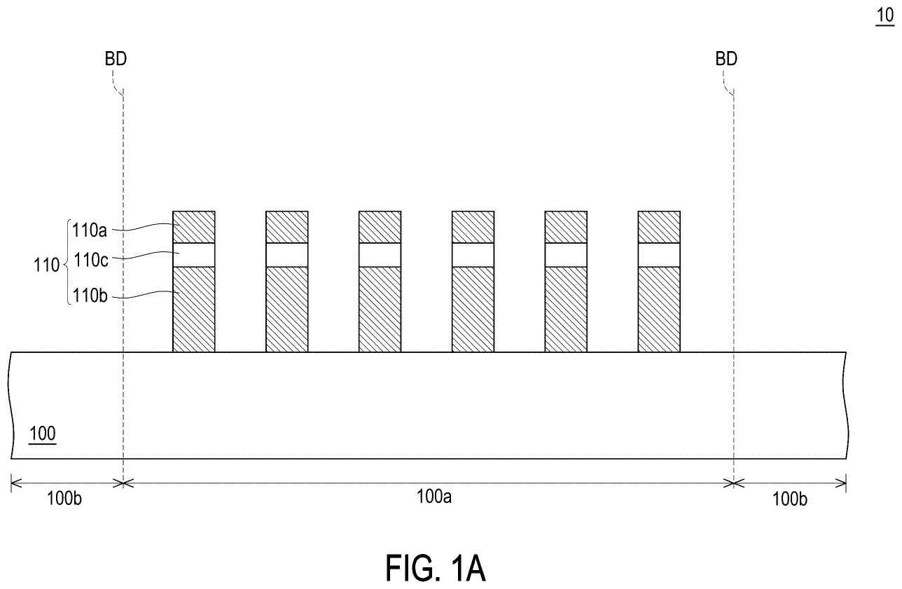

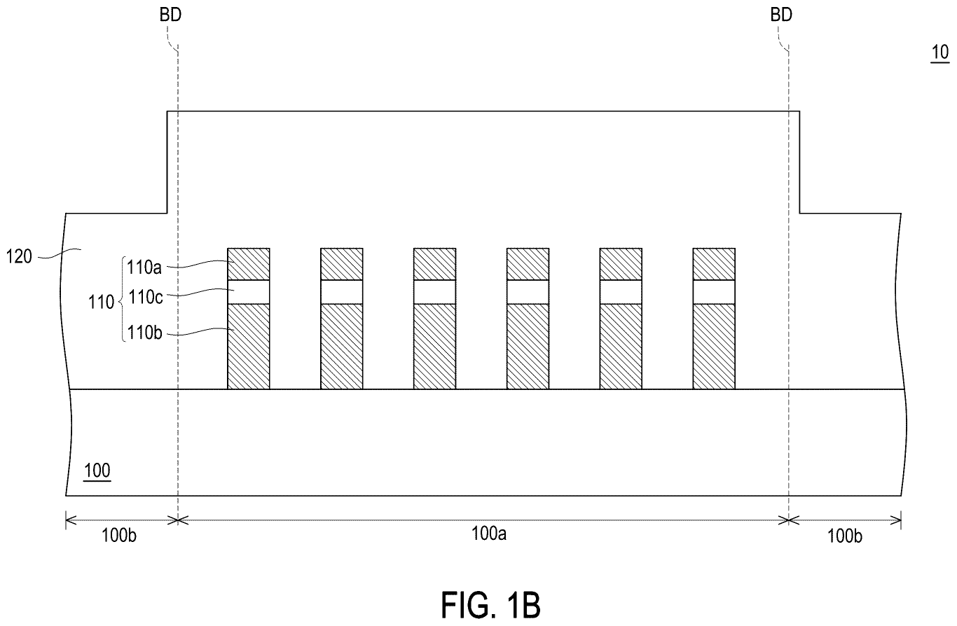

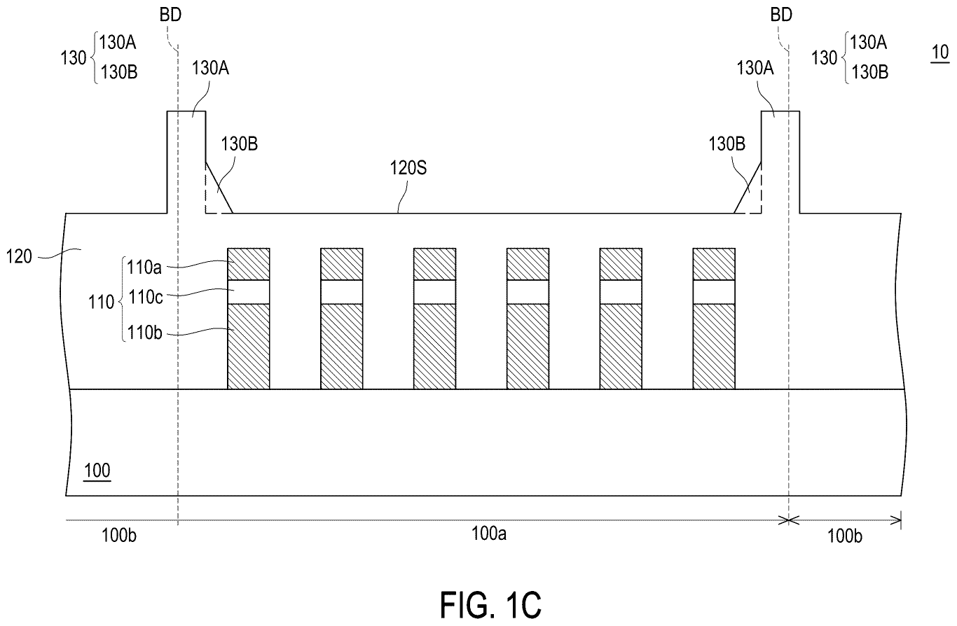

FIG. 1A to FIG. 1C are schematic cross-sectional views of a manufacturing process of a semiconductor structure 10 according to a first embodiment of the disclosure.

First, referring to FIG. 1A, a substrate 100 is provided. In the embodiment, the substrate 100 may be a silicon substrate, but the disclosure is not limited thereto. The substrate 100 has a memory device region 100a and a peripheral region 100b surrounding the memory device region 100a. There is a boundary BD between the memory device region 100a and the peripheral region 100b. In the embodiment, the peripheral region 100b may be a region where components other than memory devices are to be formed, and the components other than memory devices may be logic components, circuit patterns, etc., but the disclosure is not limited thereto.

Next, a memory device 110 is formed on the substrate 100 in the memory device region 100a, and peripheral components, such as logic elements, circuit patterns, etc., are formed on the substrate 100 in the peripheral region 100b. In FIG. 1A, the peripheral components are not shown for clarity of the drawing, but are well known to those skilled in the art. In addition, in the embodiment, the memory device 110 may be a memory device including a magnetic tunnel junction (MTJ) structure, but the disclosure is not limited thereto. In other embodiments, the memory device 110 may be any type of memory device.

For example, in the embodiment, the memory device 110 includes a top electrode 110a, a bottom electrode 110b, and a magnetic tunnel junction structure 110c disposed between the top electrode 110a and the bottom electrode 110b. The memory devices 110 are arranged in an array on the substrate 100 in the memory device region 100a. In FIG. 1A, the number of the memory devices 110 is only exemplary, and the disclosure is not limited thereto. Generally speaking, compared with various peripheral components in the peripheral region 100b, the memory device 110 in the memory device region 100a usually has a larger thickness.

Next, referring to FIG. 1B, a dielectric layer 120 is formed on the substrate 100. The dielectric layer 120 serves as an inter-layer dielectric (ILD) layer. The dielectric layer 120 covers the memory device 110 in the memory device region 100a and the peripheral components in the peripheral region 100b. Since the memory device 110 in the memory device region 100a has a larger thickness than various peripheral components in the peripheral region 100b, after the dielectric layer 120 is formed, a top surface of the dielectric layer 120 in the memory device region 100a will be significantly higher than a top surface of the dielectric layer 120 in the peripheral region 100b. That is, there is a certain degree of height difference D between the top surfaces of the dielectric layer 120 in the memory device region 100a and the peripheral region 100b. In the current semiconductor manufacturing process, in order to effectively planarize

film layers with significant height differences, an etching-back process is usually performed on the film layers with larger thicknesses before chemical mechanical polishing is used for comprehensive planarization to reduce the thickness difference of the film layers in advance, so that the loading of subsequent chemical mechanical polishing can be reduced.

The aforementioned etching-back process often utilizes a reverse mask that forms the mask of the memory device region 100a with an etching process to remove most of the dielectric layer 120 on the memory device region 100a. However, an annular dielectric layer that still has a relatively high height is often left at the boundary BD between the memory device region 100a and the peripheral region 100b.

However, it is often due to comprehensive factors such as the relatively tall memory device 110, the height difference D after the dielectric layer 120 is formed, and the use of reverse mask and etching-back process that the annular dielectric layer will generate a sub-trench at the bottom of its inner sidewalls. Such a sub-trench will cause cracks to occur at the bottom of the entire annular dielectric layer as a result of the annular dielectric layer being subjected to excessive stress during the subsequent chemical mechanical polishing process, or even cause the entire annular dielectric layer to be cracked and removed, resulting in a large-scale recess and causing the exposure of the underlying via plug, or cause the conductive material that is used to form the circuit pattern to fill in the recess when forming a circuit pattern on the memory device 120 in the subsequent process, thereby generating bridging and other structures that have a negative impact on electrical properties. Even if no cracks or recesses occur in this sub-trench, residues from subsequent processes will accumulate here, causing negative impacts on the process and electrical properties.

Therefore, the disclosure provides a semiconductor structure and a manufacturing method thereof to solve the above problems, which will be explained below.

After that, referring to FIG. 1C, after the dielectric layer 120 is formed, the etching-back process is performed to pattern the dielectric layer 120 in the memory device region 100a to form a surface 120S on the dielectric layer 120 on the memory device 110, and an annular portion 130 is formed at the top of the dielectric layer adjacent to the boundary BD between the memory device region 100a and the peripheral region 100b.

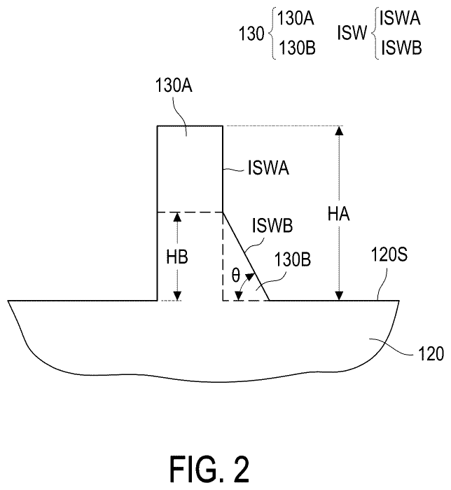

Continuing to refer to FIG. 1C, the annular portion 130 includes a vertical portion 130A and an inclined portion 130B, and the inclined portion 130B is adjacent to the vertical portion 130A. The inclined portion 130B is located inside the annular portion 130, such that an inner sidewall ISWA of the vertical portion 130A and an inner sidewall ISWB of the inclined portion 130B form an inner sidewall ISW of the annular portion 130, as shown in FIG. 2.

Referring to FIG. 2, in which a height HB of the inclined portion 130B is lower than a height HA of the vertical portion 130A. Alternatively, the height HB of the inclined portion 130B is equal to the height HA of the vertical portion 130A (not shown). The height HB of the inclined portion 130B may be 80 to 100% of the height HA of the vertical portion 130A.

Continuing to refer to FIG. 2, which is an enlarged view of the annular portion in FIG. 1C. The inclined portion 130B has an inclination angle θ of 40 to 80 degrees relative to the surface 120S of the dielectric layer 120, and more preferably an inclination angle θ of 50 to 70 degrees.

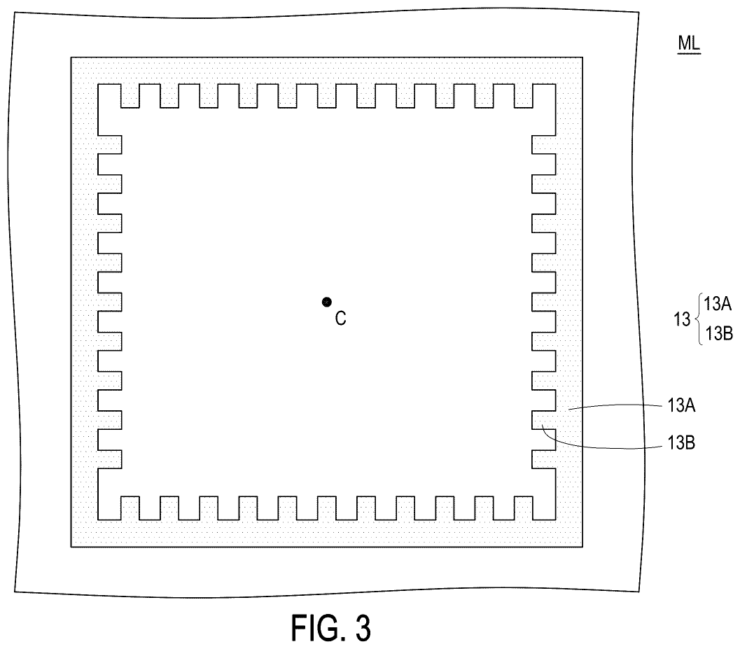

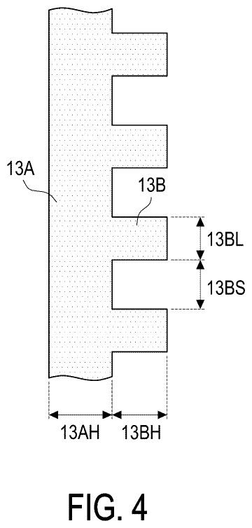

Referring to FIG. 1C, FIG. 2, FIG. 3, and FIG. 4 together for the following description, FIG. 3 is a schematic view of a mask having a comb-shaped layout pattern used in the annular portion in FIG. 1C, and FIG. 4 is an enlarged view of the comb-shaped layout pattern in FIG. 3 to illustrate that the inclined portion 130 can be formed by having a mask ML with a comb-shaped layout pattern.

A comb-shaped layout pattern 13 of the mask ML includes a comb beam portion 13A and a comb tooth portion 13B. After the lithography process, the vertical portion 130A and the inclined portion 130B of the annular portion 130 of the dielectric layer 120 are respectively formed. More specifically, after the lithography process, the comb tooth portion 13B of the comb-shaped layout pattern 13 of the mask ML will cause the comb tooth portion 13B to produce an effect similar to a semi-transparent mask in its entire width 13BL and spacing 13BS. That is, the overall transmittance of the comb tooth portion 13B at its width 13BL and spacing 13BS is between the comb beam portion 13A and other unpatterned portions to form the inclined portion 130B adjacent the vertical portion 130A. That is, the special layout pattern of the mask ML is used to simultaneously form the vertical portion 130A and the inclined portion 130B on the dielectric layer 120.

The aforementioned lithography process can be a general lithography process or a defocused lithography process. That is to say, the disclosure can use the comb-shaped layout pattern 13 and the general lithography process to simultaneously form the vertical portion 130A and the inclined portion 130B on the dielectric layer 120; the comb-shaped layout pattern 13 and the defocused lithography process can also be used to simultaneously form the vertical portion 130A and the inclined portion 130B on the dielectric layer 120 to obtain better effects.

Referring to FIG. 4, a height 13BH of the comb tooth portion 13B is 40 to 100% of a height 13AH of the comb beam portion 13A, more preferably 50 to 90%, and most preferably 60 to 80%. A ratio of the width 13BL of the comb tooth portion 13B to the spacing 13BS of the comb tooth portion 13B is 1:2 to 1:3.

The comb-shaped layout pattern 13 is formed on the dielectric layer 120 using general lithography or defocused lithography. The inclined portion 130B is formed by general lithography or defocused lithography and the comb tooth portion 13B of the comb-shaped layout pattern 13 of the mask ML. The process conditions for defocused lithography include a deviation from a focus position by 0.3 to 0.8 microns, more preferably 0.4 to 0.7 microns, and most preferably 0.5 to 0.6 microns. The process conditions for defocused lithography include a deviation from a target depth of field (DOF) by 70 to 90%, preferably 75 to 85%, and more preferably, 77 to 83%.

The inclined portion 130B adjacent to the vertical portion 130A can reinforce the vertical portion 130A and prevent the annular dielectric layer from generating the sub-trench at the bottom of its inner sidewalls, such that cracks may be prevented from occurring at the bottom of the entire annular dielectric layer as a result of the sub-trench being subjected to excessive stress during the subsequent chemical mechanical polishing process, problems such as large-scale recesses resulting from the entire annular dielectric layer being cracked and removed may be prevented, underlying via plugs may be prevented from being exposed, or the conductive material used to form the circuit patterns may be prevented from filling in the recesses when forming circuit patterns on the memory device 120 in subsequent processes so as to prevent bridging and other structures that have a negative impact on electrical properties from generating. It also solves the negative impact on the process and electrical properties caused by the existence of the sub-trench at the bottom of the inner sidewalls of the dielectric layer, where residues from subsequent processes accumulate.

### Second Embodiment

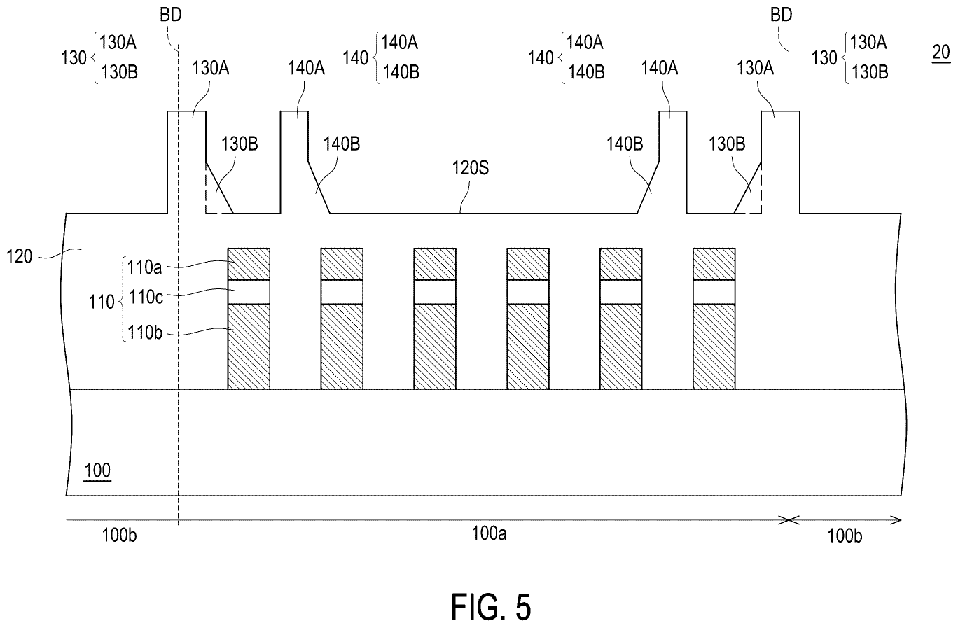

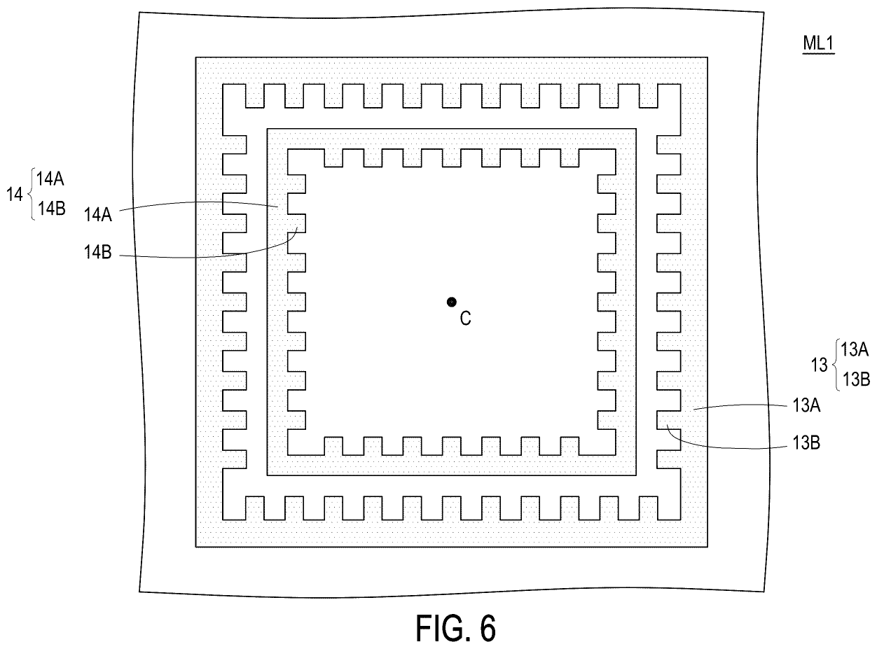

FIG. 5 is a schematic cross-sectional view of a semiconductor structure 20 according to a second embodiment of the disclosure. FIG. 6 is a schematic view of a mask having a comb-shaped layout pattern used in the annular portion and the auxiliary portion in FIG. 5. Please refer to FIG. 5 and FIG. 6 together for the following description.

In the embodiment, the same elements as those in the first embodiment will be denoted by the same reference numerals and a detailed description thereof will be omitted.

The difference between the embodiment and the first embodiment lies in that: referring to FIG. 5, while patterning the dielectric layer 120 to form the annular portion 130, an auxiliary portion 140 may also be formed on the dielectric layer 120 located in the memory device region 100a. The auxiliary portion 140 is located at the top of the dielectric layer 120, is located in a region surrounded by the annular portion 130, and is concentric with the annular portion 130 with respect to a center C, as shown in FIG. 6, so as to ensure the uniformity of comprehensive planarization in subsequent chemical mechanical polishing.

Since the annular portion 130 and the auxiliary portion 140 are formed simultaneously, a top surface of the annular portion 130 and a top surface of the auxiliary portion 140 may be coplanar.

Viewed from a top view of the substrate 100, the auxiliary portion 140 may include an annular pattern, as shown in FIG. 6.

Referring to FIG. 5, the auxiliary portion 140 includes an auxiliary vertical portion 140A and an auxiliary inclined portion 140B, and the auxiliary inclined portion 140B is adjacent to the auxiliary vertical portion 140A. The auxiliary inclined portion 140B is located inside the auxiliary vertical portion 140A, so that an inner sidewall of the auxiliary vertical portion 140A and an inner sidewall of the auxiliary inclined portion 140B form an inner sidewall of the auxiliary portion 140.

Referring to FIG. 5, a height of the auxiliary inclined portion 140B is lower than a height of the auxiliary vertical portion 140A, or a height of the auxiliary inclined portion 140B is equal to a height of the auxiliary vertical portion 140A (not shown). A height of the auxiliary portion 140 may be lower than, equal to, or higher than the height of the annular portion 130 as desired.

The annular portion 130 and the auxiliary portion 140 shown in FIG. 5, similar to the first embodiment of the disclosure, can be formed by a first mask ML1 having comb-shaped layout patterns 13 and 14 as shown in FIG. 6 and a general lithography process; it can also be formed by the first mask ML1 having the comb-shaped layout patterns 13 and 14 and a defocused lithography process to obtain better effects. The comb-shaped layout pattern 13 includes the comb beam portion 13A and the comb tooth portion 13B, and the comb-shaped layout pattern 14 includes a comb beam portion 14A and a comb tooth portion 14B. Similar to the first embodiment of the disclosure, the annular portion 130 and the auxiliary portion 140 of the dielectric layer 120 are formed through the above-mentioned comb-shaped layout patterns 13 and 14, respectively. Furthermore, the comb beam portions 13A and 14A are used to form the vertical portion 130A and the auxiliary vertical portion 140A, respectively, and the comb tooth portions 13B and 14B are used to form the inclined portion 130B and the auxiliary inclined portion 140B, respectively.

The comb-shaped layout pattern 14 forming the auxiliary portion 140 may be formed with reference to the comb-shaped layout pattern 13 forming the annular portion 130. That is, the comb-shaped layout pattern 14 forming the auxiliary portion 140 may be generated by using the comb-shaped layout pattern 13 with reference to data such as the height ratio of the comb beam portion 13A to the comb tooth portion 13B, the width 13BL of the comb tooth portion 13B and the spacing 13BS of the comb tooth portion 13B, etc., and comprehensively taking into account various aspects such as the spatial distribution of the overall layout pattern, the thickness and thickness difference of the film layer to be patterned, and the lithography etching process, etc.,

The auxiliary portion 140 of the second embodiment is as described in the aforementioned first embodiment. Since it has the auxiliary inclined portion 140B to reinforce the auxiliary portion 140, sub-trenches and cracks may be prevented from forming at the bottom of the inner sidewall of the auxiliary portion 140, so that materials from subsequent processes may be prevented from accumulating therein, or large-scale recesses may be prevented from occurring due to excessive stress that results in fractures during the comprehensive planarization by chemical mechanical polishing.

### Third Embodiment

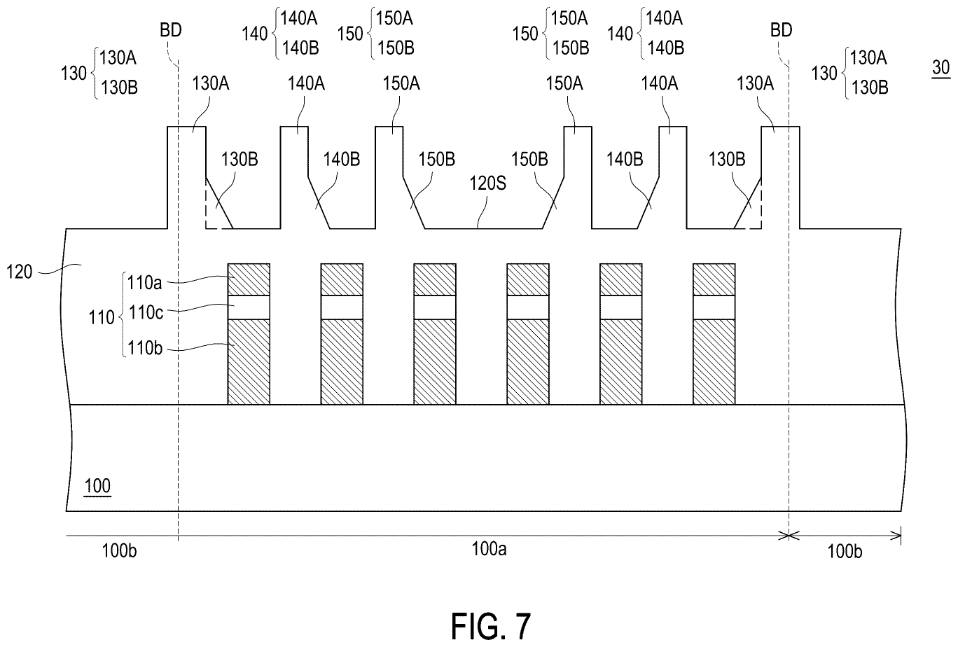

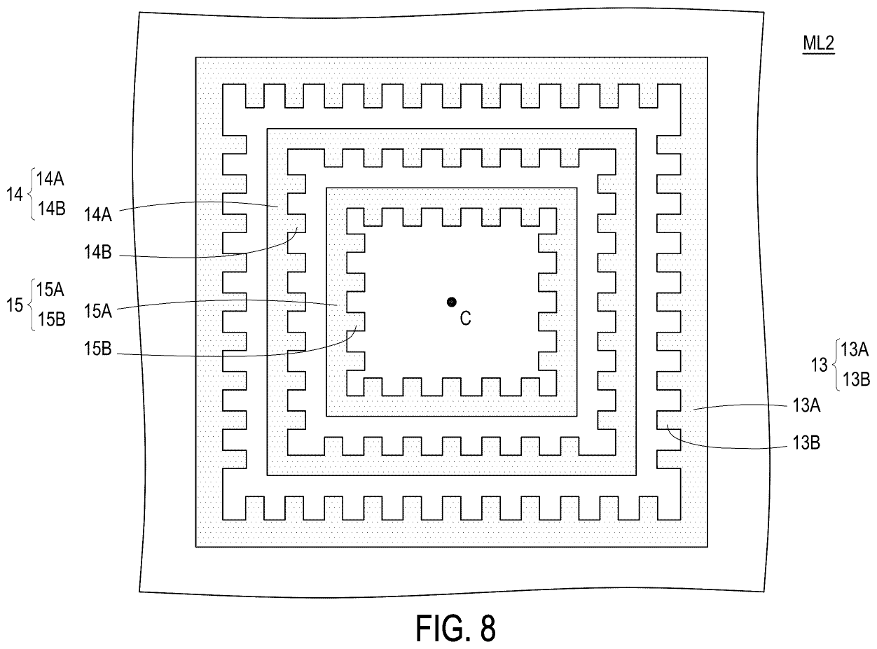

FIG. 7 is a schematic cross-sectional view of a semiconductor structure 30 according to a third embodiment of the disclosure. FIG. 8 is a schematic view of a second mask ML2 having comb-shaped layout patterns 13, 14, and 15 used in the annular portion and the auxiliary portion in FIG. 5. Please refer to FIG. 7 and FIG. 8 together for the following description.

In the embodiment, the same elements as those in the first embodiment and the second embodiment will be denoted by the same reference numerals and a detailed description thereof will be omitted.

The difference between the embodiment and the second embodiment lies in that the auxiliary portions 140 and 150 may include a plurality of annular patterns, as shown in FIG. 7 and FIG. 8. The auxiliary portions 140 and 150 may include two annular patterns, but are not limited thereto and may include more.

As described in the first and second embodiments, the annular portion 130, the auxiliary portion 140, and the auxiliary portion 150 of the third embodiment can be formed by a second mask ML2 having comb-shaped layout patterns 13, 14, and 15 as shown in FIG. 8 and a general lithography process; it can also be formed by the second mask ML2 having the comb-shaped layout patterns 13, 14, and 15 and a defocused lithography process to obtain better effects.

The auxiliary portion 150 is concentric with the auxiliary portion 140 and the annular portion 130 with respect to the center C, as shown in FIG. 8, so as to ensure the uniformity of comprehensive planarization in subsequent chemical mechanical polishing.

Since the annular portion 130 and the auxiliary portions 140 and 150 are formed simultaneously, the top surface of the annular portion 130 and the top surfaces of the auxiliary portions 140 and 150 may be coplanar.

In addition to the annular portion 130 and the auxiliary portion 140 formed in the second embodiment, referring to FIG. 7, the auxiliary portion 150 is also included. Like the first and second embodiments, the auxiliary portion 150 of the third embodiment includes an auxiliary vertical portion 150A and an auxiliary inclined portion 150B, and the auxiliary inclined portion 150B is adjacent to the auxiliary vertical portion 150A. The auxiliary inclined portion 150B is located inside the auxiliary vertical portion 150A, so that an inner sidewall of the auxiliary vertical portion 150A and an inner sidewall of the auxiliary inclined portion 150B form an inner sidewall of the auxiliary portion 150.

Referring to FIG. 7, a height of the auxiliary inclined portion 150B is lower than a height of the auxiliary vertical portion 150A, or a height of the auxiliary inclined portion 150B is equal to a height of the auxiliary vertical portion 150A (not shown). A height of the auxiliary portion 150 may be lower than, equal to, or higher than the height of the annular portion 130 and the height of the auxiliary portion 140 as desired.

The annular portion 130 and the auxiliary portions 140 and 150 shown in FIG. 7 can be formed by the mask ML2 having the comb-shaped layout patterns 13, 14, and 15 as shown in FIG. 8 and a general lithography process; it can also be formed by the mask ML2 having the comb-shaped layout patterns 13, 14, and 15 and a defocused lithography process to achieve better effects.

The comb-shaped layout pattern 13 includes the comb beam portion 13A and the comb tooth portion 13B. The comb-shaped layout pattern 14 includes the comb beam portion 14A and the comb tooth portion 14B. The comb-shaped layout pattern 15 includes a comb beam portion 15A and a comb tooth portion 15B. Similar to the first embodiment of the disclosure and the description of the first embodiment, the annular portion 130 and the auxiliary portions 140 and 150 of the dielectric layer 120 are respectively formed through the above-mentioned comb-shaped layout patterns 13, 14, and 15. Moreover, the comb beam portions 13A, 14A, and 15A are used to respectively form the vertical portion 130A and the auxiliary vertical portions 140A and 150A, and the comb tooth portions 13B, 14B, and 15B are used to respectively form the inclined portion 130B and the auxiliary inclined portions 140B and 150B.

The comb-shaped layout pattern 15 forming the auxiliary portion 150, like the comb-shaped layout pattern 14 forming the auxiliary portion 140, can be formed with reference to the comb-shaped layout pattern 13 forming the annular portion 130 and the comb-shaped layout pattern 14 forming the auxiliary portion 140. That is, the comb-shaped layout pattern 15 forming the auxiliary portion 150 may be generated by using the comb-shaped layout patterns 13 and 14 and comprehensively taking into account various aspects such as the spatial distribution of the overall layout pattern, the thickness and thickness difference of the film layer to be patterned, and the lithography etching process, etc.

The auxiliary portion 150 of the third embodiment is as described in the aforementioned first and second embodiments. Since it has the auxiliary inclined portion 150B to reinforce the auxiliary portion 150, sub-trenches and cracks may be prevented from forming at the bottom of the inner sidewall of the auxiliary portion 150, so that materials from subsequent processes may be prevented from accumulating therein, or large-scale recesses may be prevented from occurring due to excessive stress resulting in fractures during the comprehensive planarization by chemical mechanical polishing.

Although the disclosure has been described with reference to the embodiments above, the embodiments are not intended to limit the disclosure. Any person skilled in the art can make some changes and modifications without departing from the spirit and scope of the disclosure. Therefore, the scope of the disclosure will be defined in the appended claims.

What is claimed is:

1. A semiconductor structure, comprising:
a substrate, comprising a memory device region and a peripheral region surrounding the memory device region;
a memory device, disposed on the substrate in the memory device region; and
a dielectric layer, disposed on the substrate, covering the memory device, having a surface on the memory device, and comprising an annular portion, wherein the annular portion is located at a top of the dielectric layer and adjacent to a boundary between the memory device region and the peripheral region, and the annular portion comprises:
a vertical portion; and
an inclined portion, adjacent to the vertical portion, wherein
an inner sidewall of the vertical portion and an inner sidewall of the inclined portion form an inner sidewall of the annular portion,
a height of the inclined portion is equal to or lower than a height of the vertical portion, and
the inclined portion is formed by a mask having a comb-shaped layout pattern.

2. The semiconductor structure according to claim 1, wherein the inclined portion has an inclination angle of 40 to 80 degrees relative to the surface of the dielectric layer.

3. The semiconductor structure according to claim 1, wherein the height of the inclined portion is 80 to 100% of the height of the vertical portion.

4. The semiconductor structure according to claim 1, wherein the comb-shaped layout pattern comprises a comb beam portion and a comb tooth portion, a height of the comb tooth portion is 40 to 100% of a height of the comb beam portion, and a ratio of a width of the comb tooth portion to a spacing of the comb tooth portion is 1:2 to 1:3.

5. The semiconductor structure according to claim 1, wherein the inclined portion is formed by the mask having the comb-shaped layout pattern and a general lithography process, or the inclined portion is formed by the mask having the comb-shaped layout pattern and a defocused lithography process.

6. The semiconductor structure according to claim 5, wherein the defocused lithography process comprises a deviation from a focus position by 0.3 to 0.8 microns.

7. The semiconductor structure according to claim 5, wherein the defocused lithography process comprises a deviation from a target depth of field (DOF) by 70 to 90%.

8. The semiconductor structure according to claim 1, wherein the dielectric layer located in the memory device region further comprises an auxiliary portion, and the auxiliary portion is located at the top of the dielectric layer, is located in a region surrounded by the annular portion, and is concentric with the annular portion.

9. The semiconductor structure according to claim 8, wherein a top surface of the annular portion and a top surface of the auxiliary portion are coplanar.

10. The semiconductor structure according to claim 8, wherein the auxiliary portion comprises one or more annular patterns when viewed from a top view above the substrate.

11. The semiconductor structure according to claim 8, wherein the auxiliary portion comprises:
an auxiliary vertical portion; and
an auxiliary inclined portion, adjacent to the auxiliary vertical portion, wherein
an inner sidewall of the auxiliary vertical portion and an inner sidewall of the auxiliary inclined portion form an inner sidewall of the auxiliary portion,
a height of the auxiliary inclined portion is equal to or lower than a height of the auxiliary vertical portion, and
the auxiliary inclined portion is formed by the mask having the comb-shaped layout pattern.

12. The semiconductor structure according to claim 1, wherein the memory device comprises a magnetic tunnel junction (MTJ) structure.

13. A manufacturing method of a semiconductor structure, comprising:
providing a substrate, wherein the substrate comprises a memory device region and a peripheral region surrounding the memory device region;
forming a memory device on the substrate in the memory device region;
forming a dielectric layer on the substrate to cover the memory device; and
patterning the dielectric layer to form a surface for the dielectric layer on the memory device and form an annular portion at a top of the dielectric layer adjacent a boundary between the memory device region and the peripheral region, wherein the annular portion comprises:
a vertical portion; and
an inclined portion, adjacent to the vertical portion, wherein
an inner sidewall of the vertical portion and an inner sidewall of the inclined portion form an inner sidewall of the annular portion,
a height of the inclined portion is equal to or lower than a height of the vertical portion, and
the inclined portion is formed by a mask having a comb-shaped layout pattern.

14. The manufacturing method of the semiconductor structure according to claim 13, wherein the inclined portion has an inclination angle of 40 to 80 degrees relative to the surface of the dielectric layer.

15. The manufacturing method of the semiconductor structure according to claim 13, wherein the height of the inclined portion is 80 to 100% of the height of the vertical portion.

16. The manufacturing method of the semiconductor structure according to claim 13, wherein the comb-shaped layout pattern comprises a comb beam portion and a comb tooth portion, a height of the comb tooth portion is 40 to 100% of a height of the comb beam portion, and a ratio of a width of the comb tooth portion to a spacing of the comb tooth portion is 1:2 to 1:3.

17. The manufacturing method of the semiconductor structure according to claim 13, wherein the inclined portion is formed by the mask having the comb-shaped layout pattern and a general lithography process, or the inclined portion is formed by the mask having the comb-shaped layout pattern and a defocused lithography process.

18. The manufacturing method of the semiconductor structure according to claim 17, wherein the defocused lithography process comprises a deviation from a focus position of 0.3 to 0.8 microns.

19. The manufacturing method of the semiconductor structure according to claim 17, wherein the defocused lithography process comprises a deviation from a target depth of field (DOF) of 70 to 90%.

20. The manufacturing method of the semiconductor structure according to claim 13, wherein while patterning the dielectric layer, an auxiliary portion is formed on the dielectric layer located in the memory device region, and the auxiliary portion is located at the top of the dielectric layer, is located in a region surrounded by the annular portion, and is concentric with the annular portion.

21. The manufacturing method of the semiconductor structure according to claim 20, wherein a top surface of the annular portion and a top surface of the auxiliary portion are coplanar.

22. The manufacturing method of the semiconductor structure according to claim 20, wherein the auxiliary portion comprises one or more annular patterns when viewed from a top view above the substrate.

23. The manufacturing method of the semiconductor structure according to claim 20, wherein the auxiliary portion comprises:
an auxiliary vertical portion; and
an auxiliary inclined portion, adjacent to the auxiliary vertical portion, wherein
an inner sidewall of the auxiliary vertical portion and an inner sidewall of the auxiliary inclined portion form an inner sidewall of the auxiliary portion,
a height of the auxiliary inclined portion is equal to or lower than a height of the auxiliary vertical portion, and
the auxiliary inclined portion is formed by the mask having the comb-shaped layout pattern.

24. The manufacturing method of the semiconductor structure according to claim 13, wherein the memory device comprises a magnetic tunnel junction (MTJ) structure.
